(19) United States
(12) Patent Application Publication
(10) Pub. No.: US 2016/0189997 A1
(43) Pub. Date: Jun. 30, 2016

(54) AUXILIARY SHEET FOR LASER DICING

(71) Applicant: Kimoto Co., Ltd., Saitama (JP)

(72) Inventors: Nobuyuki Abe, Mie (JP); Takayuki Kurashina, Saitama (JP)

(73) Assignee: Kimoto Co., Ltd.

(21) Appl. No.: 14/969,540

(22) Filed: Dec. 15, 2015

(30) Foreign Application Priority Data
Dec. 24, 2014 (JP) 2014259688

(51) Int. Cl. H01L 21/683

(52) U.S. Cl. CPC H01L 21/6836; H01L 2221/68327

(57) ABSTRACT

An auxiliary sheet for laser dicing is provided, with which partial adhesion of a substrate film to a processing table is not caused even when dicing a workpiece by using a high output laser light and at a high scan speed, therefore, workability does not decline after that. An adhesive layer is stacked on one surface of the substrate film in the laser dicing auxiliary sheet and a functional layer is stacked on the other surface (a surface to contact with a processing chuck table during dicing), and the functional layer is formed by using a mixture containing metal oxide fine particles, in which an average particle diameter of the primary particle is 5 to 400 nm, and emulsion particles of a thermoplastic resin as a binder material.

### BACKGROUND OF THE INVENTION

1. Field of the Invention

The present invention relates to an auxiliary sheet for laser dicing used for dicing a workpiece, such as a semiconductor wafer, with a laser light.

2. Description of the Related Art

Methods for cutting a semiconductor wafer by using a laser light, by which damages due to heat is suppressed and highly precise processing is possible, are known. This technique is to fix a workpiece obtained, for example, by forming various circuits on a substrate and performing a surface treatment thereon, to a dicing auxiliary sheet and to dice the workpiece with a laser light passing at a predetermined speed with respect to the workpiece and to chip into small pieces (Patent Document 1). An auxiliary sheet for dicing configured by a substrate including a substrate film and an adhesive layer formed on a surface of the substrate has been also proposed, wherein the adhesive layer is cut by a laser light while the substrate film is not cut (that means, it is not cut fully) (Patent Document 2).

However, when using a laser light for dicing a workpiece, it is difficult to control to cut only an adhesive layer and not a substrate film. Even if only an adhesive layer can be cut, a part of a back surface of the substrate film sometimes adheres strongly to a chuck table for processing in a dicing apparatus. Therefore, that sometimes causes a trouble in later steps of removing the workpieces by stretching the substrate film and collecting them individually, etc.

To eliminate such a disadvantage, a technique of forming a specific melt protective layer on a back surface (a side facing to a chuck table) of the substrate film has been proposed (Patent Document 3). The Patent Document 3 describes use of inorganic particles having a particle diameter of 1 μm to some hundreds of μm to be blended in the melt protective layer (paragraphs [0016] and [0054]).

### RELATED ART DOCUMENTS

### Patent Documents

[Patent Document 1] Japanese Patent Unexamined Publication (Kokai) No. 2004-79746

[Patent Document 2] Japanese Patent Unexamined Publication (Kokai) No. 2002-343747

[Patent Document 3] Japanese Patent Unexamined Publication (Kokai) No. 2008-49346

### SUMMARY OF THE INVENTION

According to the technique in the patent document 3, it is possible to effectively prevent melting of a substrate film caused by partially intensified laser light energy at a part irradiated with the laser light, consequently, it is possible to prevent the phenomenon that the back surface of the substrate film partially adheres to a processing table in a dicing apparatus.

In recent years, there have been demands for a further reduction in size and thickness of semiconductor chips and other workpieces to be chipped. To respond thereto, substrates of semiconductor wafers and optical device wafers, etc. have to be also thinner. When substrates of semiconductor wafers and optical device wafers, etc. are made thinner, it normally results in a decline of strength. Therefore, to secure that, substrates having higher hardness than before, for example, a sapphire substrate and a substrate obtained by depositing silver on copper, etc. have started to be used.

When dicing a semiconductor wafer, etc. having such a highly hard substrate, the irradiation condition of a laser light is loose (average output: 5 W and scan speed: 20 mm/sec. paragraph [0052]) in the Patent Document 3, an chipping operation of the workpiece having a highly hard substrate takes time under such condition (a long-time irradiation is required to cut the workpiece fully), and there arises concern over a decline of productivity. Thus, an experiment was done with a higher irradiation output of a laser light with a higher scan speed, wherein melting of the substrate film was observed at the irradiated part by the laser light, as a result, there arose a phenomenon that a back surface of the substrate film adheres to the processing table in the dicing apparatus.

As an aspect of the present invention, there is provided an auxiliary sheet for laser dicing, with which even when dicing a workpiece by using a high-output laser light with a high scan speed, partial adhesion of a substrate film to the processing table is not caused and workability thereafter is not deteriorated.

The present inventors built a hypothesis that, in the technique in the patent document 3, the reason why melting was observed at a laser light irradiated part on the substrate film when a laser light irradiation output was increased and a scan speed was set high was because a particle diameter of particles to be blended was relatively large (1 μm or more) and devoted themselves in studying. As a result, they found that they could obtain an auxiliary sheet for laser dicing provided with the features as explained above by stacking a functional layer formed by using a mixture having a specific composition comprising fine particles together with emulsion particles of a thermoplastic resin as a binder material on the back surface (a surface to contact with a processing chuck table when dicing) of the substrate film, and completed the present invention.

The auxiliary sheet for laser dicing of the present invention is configured that an adhesive layer is stacked on one surface of a substrate film, a functional layer is stacked on the other surface of the substrate film, and the functional layer is formed by using a mixture containing metal oxide fine particles, in which an average particle diameter of primary particle is 5 to 400 nm, and emulsion particles of a thermoplastic resin as a binder material.

The present invention includes the following aspects.

(1) Preferably, a thickness of the functional layer is adjusted to 0.5 μm or more and 10 μm or less.
(2) Preferably, surface roughness (Ra) on an exposed side of the functional layer is adjusted to 0.2 μm or more and 1.5 μm or less.
(3) When a total solid content in the mixture to be used for the functional layer is assumed to be 100 mass %, a ratio of the metal oxide particles to emulsion particles of a thermoplastic resin is adjusted to 10-90 mass %:90-10 mass % in terms of solid content.

Since the auxiliary sheet for laser dicing of the present invention has a functional layer formed by using a mixture having a specific composition stacked on a back surface (a surface to contact with a processing chuck table when dicing) of a substrate film, the substrate film does not adhere partially to a processing table even when dicing a workpiece by using a high-output laser light with a high scan speed. Therefore, workability thereafter is not deteriorated.

### DETAILED DESCRIPTION OF THE INVENTION

Below, one surface of a substrate film is also referred to as “a front surface” and the other surface thereof (an opposite surface of “the front surface”) as “a back surface”.

The auxiliary sheet for laser dicing of the present invention is configured mainly by a substrate film, an adhesive layer stacked on a front surface of the substrate film and a functional layer stacked on a back surface of the substrate film. Below, an embodiment of the respective components will be explained with an example of a processing operation of a semiconductor wafer.

<Functional Layer>

A functional layer to be stacked on the back surface of the substrate film is a layer, which does not melt or is hard to melt by being irradiated with a laser light and is for protecting the back surface of the substrate film, so that the substrate film does not adhere to a processing table, etc. due to melting, etc. of the substrate film.

The functional layer is formed by a mixture comprising metal oxide fine particles and a thermoplastic resin as a binder material.

As the metal oxide fine particles, for example, fine particles of an oxide of silicon, oxide of tin, oxide of aluminum and oxide of zirconium, etc. may be mentioned. Specifically, colloidal silica, colloidal alumina, zirconium oxide-silica composite sol, tin oxide-silica composite sol, zinc antimonite sol, phosphor-doped tin oxide aqueous dispersion sol, and fine colloidal zirconia aqueous sol, etc. may be mentioned. Among them, colloidal silica is preferably used. Particularly, colloidal silica subjected to a surface treatment with aluminum is preferably used. As a shape thereof, those having a sphere shape are preferably used.

Metal oxide fine particles to be used in the present invention is required to have an average particle diameter of primary particles before coagulation being 5 nm or more, preferably 10 nm or more and 400 nm or less, preferably 250 nm or less, more preferably 150 nm or less, furthermore preferably 100 nm or less and most preferably 50 nm or less. Even though using metal oxide fine particles, if an average particle diameter of primary particles thereof is less than 5 nm or more than 400 nm, adhesion to a processing table, etc. due to melting, etc. of the substrate film cannot be prevented at a part where laser light energy converges even though a coat film (functional layer) is formed on the back surface of the substrate film. The reason why an average particle diameter of primary particles of metal oxide fine particles to be blended affects melting, etc. of the substrate film at the part with converged laser light energy is not clear, however, when the average particle diameter of primary particles of metal oxide fine particles is small, a laser light is scattered or absorbed by the metal oxide fine particles and the laser light intensity is reduced. It is considered that when the laser light intensity is reduced, melting of a resin in the functional layer is suppressed, consequently, it become hard to melt.

An average particle diameter as above may be measured by using a particle diameter distribution measurement apparatus, such as a dynamic light scattering method particle diameter distribution measurement apparatus (“Submicron Particle Analyzer Delsa Nano S” made by Beckman Coulter, Inc.), etc. Also, for example, an image analysis using a transmission type electron microscope (TEM) or scanning type electron microscope (SEM) may be used for the measurement.

As colloidal silica satisfying the average particle diameter as above, market-available products may be used. As those, for example, SNOWTEX ST-50 (particle diameter 20 to 24 nm), SNOWTEX ST-30MI (particle diameter 20 to 24 nm), SNOWTEX ST-C (particle diameter 10 to 15 nm with an aluminum surface treatment), SNOWTEX ST-CM (particle diameter 20 to 24 nm with an aluminum surface treatment), SNOWTEX ST-N (particle diameter 10 to 15 nm), SNOWTEX ST-XL (particle diameter 40 to 50 nm), SNOWTEX ST-YL (particle diameter 50 to 80 nm, alkaline sol), SNOWTEX ST-ZL (particle diameter 70 to 90 nm), SNOWTEX MP-1040 (particle diameter 100 nm), SNOWTEX MP-2040 (particle diameter 200 nm), SNOWTEX MP-3040 (particle diameter 300 nm) (those listed above made by NISSAN CHEMICAL INDUSTRIES, LTD.) and Adelite AT-50 (particle diameter 20 to 30 nm) (made by ADEKA CORPORATION), etc. may be used. The colloidal silica mentioned above may be used alone or in combination of two or more kinds.

Also, as to other metal oxide fine particles other than colloidal silica satisfying the average particle diameter above, market-available products may be used. For example, NanoUse ZR-30BS (particle diameter 30 to 80 nm, alkaline sol), NanoUse ZR-40BL (particle diameter 70 to 110 nm, alkaline sol), NanoUse ZR-30BFN (particle diameter 10 to 30 nm, alkaline sol), CELNAX CX-S series (CX-S301H, etc.), ALUMINASOL 100 and ALUMINASOL 200 (those listed above made by NISSAN CHEMICAL INDUSTRIES, LTD.) may be used.

As a thermoplastic resin, for example, polyolefin type resins, polyamide type resins and polyester type resins (PET, etc.), etc. may be mentioned and they may be used alone or in combination of two or more kinds.

Polyolefin type resins are not particularly limited and a variety of polyolefin may be used. For example, an ethylene homopolymer, propylene homopolymer, ethylene-propylene copolymer, ethylene-α-olefin copolymer and propylene-α-olefin copolymer, etc. may be mentioned. The α-olefins mentioned above are normally 3-20 C unsaturated hydrocarbon compounds and propylene, 1-buten, 1-penten, 1-hexene, 1-hepten, 3-methyl-1-buten and 4-methyl-1-penten, etc. may be mentioned.

As polyolefin type resins, those being acid-modified, namely, including an acid group (for example, unsaturated carboxylic acid component, etc.) are preferable.

A content of unsaturated carboxylic acid component in an acid-modified polyolefin type resin is preferably small as 0.1 to 30 mass % or so. This amount is preferably 0.5 to 22 mass %, more preferably 0.5 to 15 mass %, furthermore preferably 1 to 10 mass % and particularly preferably 1 to 5 mass % in terms of easiness of making a resin aqueous, which will be explained later. When a content of unsaturated carboxylic acid component exceeds 30 mass %, water repellency and adhesiveness with a substrate are liable to decline.

Unsaturated carboxylic acid components are introduced by unsaturated carboxylic acids or anhydrides thereof, and specifically acrylic acid, methacrylic acid, maleic acid, maleic anhydride, itaconic acid, itaconic anhydride, fumaric acid, crotonic acid, unsaturated dicarboxylic acid half ester and half amide, etc. may be mentioned. Among them, acrylic acid, methacrylic acid, maleic acid and maleic anhydride are preferable and particularly acrylic acid and maleic anhydride are preferable. Also, unsaturated carboxylic acid components may be copolymerized in an acid-modified polyolefin type resin, a form thereof is not limited and, for example, a random copolymerization, block copolymerization and graft copolymerization, etc. may be mentioned.

These polyolefin type resins may be used alone or in combination of two or more kinds. Namely, the polyolefin type resin may be a mixture of polymers mentioned above.

Polyamide resins are polymers having a chain shaped skeleton formed by a plurality of monomers polymerized by amide bonding (—NH—CO—).

As monomers to configure a polyamide resin, aminocaproic acid, aminoundecaoic acid, aminododecanoic acid, paraaminomethyl benzoic acid and other amino acids, ε-caprolactam, undecane lactam, ω-lauryl lactam, and other lactams may be mentioned. These monomers may be used alone or in combination of two or more kinds.

A polyamide resin may be also obtained by copolymerizing diamine and carboxylic acid. In that case, as diamine being a monomer, ethylene diamine, 1,3-diaminopropane, 1,4-diaminobutane, 1,6-diaminohexane, 1,7-diaminoheptane, 1,8-diaminooxtane, 1,9-diamino nonane, 1,10-diaminodecane, 1,11-diaminoundecane, 1,12-diaminodecane, 1,13-diaminotridecane, 1,14-diaminotetradecane, 1,15-diaminopentadecane, 1,16-diaminohexadecane, 1,17-diaminoheptadecane, 1,18-diaminooctadecae 1,19-diamino nonadecane, 1,20-diamino eicosane, 2-methyl-1,5-diaminopentane, 2-methyl-1,8-diaminooctane and other aliphatic diamines, cyclohexane diamine, bis-(4-aminocyclohexyl)methane and other alicyclic diamines, xylylene diamine (p-phenylene diamine and m-phenylene diamine, etc.) and other aromatic diamines, etc. may be mentioned. These monomers may be used alone or in combination of two or more kinds. As dicarboxylic acids being monomers, oxalic acid, malonic acid, succinic acid, glutaric acid, adipic acid, pimelic acid, suberic acid, azelaic acid, sebacic acid, undecanedioic acid, dodecanedioic acid, brassylic acid, tetradecanedioic acid, pentadecanedioic acid, octadecanedioic acid and other aliphatic dicarboxylic acids, cyclohexanedicarboxylic acid and other alicyclic dicarboxylic acids, phthalic acid, terephthalic acid, isophthalic acid, naphthalene dicarboxylic acid and other aromatic dicarboxylic acids, etc. may be mentioned. These monomers may be used alone or in combination of two or more kinds.

These polyamides may be used alone or in combination of two or more kinds.

In the present invention, a binder material (the thermoplastic resins mentioned above) in the mixture has to be emulsion particles. When emulsion particles are used, the metal oxide very fine particles mentioned above can be bound at points, by which a binding force is liable to be stronger comparing with the case of using a same amount of solvent soluble binder material, so that metal oxide fine particles can be bound with a smaller amount of binder material.

Namely, in the present invention, the thermoplastic resins mentioned above supplied in an aqueous emulsion state are used.

Among them, it is preferable that aqueous emulsion (aqueous dispersion) of the thermoplastic resins mentioned above to be used in the present invention do not substantially include nonvolatile auxiliary agent for converting into aqueous.

Here, “substantially do not include nonvolatile auxiliary agent for converting into aqueous” means that by not adding to the system any nonvolatile auxiliary for converting into aqueous when producing aqueous emulsion of the thermoplastic resin mentioned above to be used in the present invention, those are not included as a result. Regarding a nonvolatile auxiliary agent for converting into aqueous, it is particularly preferable when a content thereof is zero in emulsion, but it may be included less than 0.1 mass % with respect to polyolefin type resin component in a range of not undermining the effect of the present invention.

Here, “an auxiliary agent for converting into aqueous” indicates chemicals or compounds to be added for the purpose of accelerating conversion into aqueous and stabilizing emulsion. “Nonvolatile” indicates having a high boiling point (for example, 300 degrees or higher) under a normal pressure or not having any boiling point.

As “a nonvolatile auxiliary agent for converting into aqueous” in the present ivention, for example, emulsifiers, compounds having a protective colloid effect, modified waxes, high acid value acid denaturation materials and water-soluble polymers, etc. may be mentioned.

As emulsion of a polyolefin resin, various emulsions of ARROWBASE (registered trademark) series by UNITIKA LTD. and Hardlen (registered trademark) series by TOYOBO CO., LTD. may be mentioned.

As emulsions of ARROWBASE series, one or more kinds from, for example, CB-1010 (PE skeleton, active ingredient concentration: 20 mass %), CB-1200 (PE skeleton, active ingredient concentration: 23 mass %), CD-1200 (PE skeleton, active ingredient concentration: 20 mass %), SB-1200 (PE skeleton, active ingredient concentration: 25 mass %), SD-1200 (PE skeleton, active ingredient concentration: 20 mass %), SE-1200 (PE skeleton, active ingredient concentration: 20 mass %, anionic), TC-4010 (PP skeleton, active ingredient concentration: 25 mass %), TD-4010 (PP skeleton, active ingredient concentration: 25 mass %), etc. may be mentioned.

As emulsions of Hardlen series, one or more kinds from chlorinated polyolefin EW-5303 (chlorine content: 17 mass %, resin concentration: 30 mass %), EW-5504 (chlorine content 16 mass %, resin concentration 40 mass %), EW-8511 (chlorine content 16 mass %, resin concentration 30 mass %), EZ-1000 (chlorine content 21 mass %, resin concentration 30 mass %), EZ-2000 (chlorine content 20 mass %, resin concentration 30 mass %), EH-801J (chlorine content 16 mass %, resin concentration 30 mass %), EW5313-4 (chlorine content 10 mass %, resin concentration 30 mass %), EW-5515 (chlorine content 15 mass %, resin concentration 30 mass %), EZ-1001 (chlorine content 17 mass %, resin concentration 30 mass %), EZ-2001 (chlorine content 14 mass %, resin concentration 30 mass %), and EZ-1001E (chlorine content 16.5 mass %, resin concentration 30 mass %), etc. may be mentioned.

As polyamide type resin emulsion, one or more kinds from model number M3-C-2225 (active ingredient concentration 25 mass %), M4-C-X025 (active ingredient concentration 25 mass %), MC-2220 (active ingredient concentration 20 mass %), MA-X020 (active ingredient concentration 20 mass %), MD-X020 (active ingredient concentration 20 mass %), ME-X025 (active ingredient concentration 25 mass %) and ME-X020 (active ingredient concentration 20 mass %), etc. may be mentioned.

A mixture to be used for forming the functional layer may be blended with additive components, such as a leveling agent, ultraviolet absorbent and antioxidant, as needed as far as not undermining the effect of the present invention.

A blending ratio of respective components in the mixture to be used for forming the functional layer is preferably metal oxide fine particles in an amount of 10 to 90 mass %, emulsion particles of a thermoplastic resin 10 to 90 mass % and additive components 0 to 10 mass % when the whole amount is assumed to be 100 mass %.

A blending ratio of metal oxide fine particles to emulsion particles of a thermoplastic resin is preferably in a range of 10 to 90 mass %:90 to 10 mass %, more preferably 35 to 65 mass %:65 to 35 mass % and furthermore preferably 40 to 60 mass %:60 to 40 mass %, respectively, in the composition above. The most preferable ratio is the metal oxide fine particles in an amount of 45 to 55 mass % and emulsion particles of a thermoplastic resin in an amount of 55 to 45 mass %. When at those ratios, it is easy to adjust surface roughness on the opposite surface (exposed side) of the substrate film in the functional layer to be formed to be in a later explained range and thereby adhesion to a processing table due to melting, etc. of the substrate film can be prevented more effectively. Particularly when the blending ratio of the metal oxide fine particles to emulsion particles of a thermoplastic resin is 45 to 55 mass %:55 to 45 mass % (1:1 substantially), the surface roughness of the functional layer becomes optimal, as a result, adhesion to a processing table due to melting, etc. of the substrate film is expected to be prevented furthermore effectively.

When a ratio of the emulsion particles of a thermoplastic resin as a binder material exceeds 90 mass %, a ratio of the metal oxide fine particles becomes less than 10 mass % and, even if a coating film (functional layer) is formed on the back surface of the substrate film, adhesion to a processing table, etc. due to melting, etc. of the substrate film cannot be prevented at a part where laser light energy converges. When a ratio of emulsion particles of a thermoplastic resin is less than 10 mass %, it becomes difficult to form a coating film (functional layer) and cracks easily arise. A blending amount of additives is 0 to 10 mass % and preferably 1 to 8 mass % in a solid content of a composition composed of metal oxide fine particles, emulsion particles of a thermoplastic resin and additive components.

The functional layer may be stacked on the back surface of the substrate film by any method. For example, a method of mixing and dispersing the respective components above in a dispersion medium, obtaining a paint (an example of a mixture), then, applying the same on the back surface of the substrate film by a well-known method in the field and drying (the application method), a method of stacking a mixed melt substance (an example of a mixture) of the respective components above on the back surface of the substrate film (the melt extrusion method) and a method of coextruding a mixture of the respective components above and a component of the substrate film and stacking a functional layer on the back surface of the substrate film (the coextrusion method), etc. may be mentioned, but it is not limited to those.

The dispersion medium in the paint in the application method is preferably an aqueous medium in terms of the environment and safety. An aqueous medium is water alone or a mixed solvent of water and water soluble organic solvent. As organic solvents, N-methyl-2-pyrrolidone (NMP), N, N-dimethylformamide, tetrahydrofuran, dimethylacetoamide, dimethyl sulfoxide, hexamethylphosphoramide, tetramethylurea, acetone, methylethylketone (MEK), γ-butyrolactone and isopropanol may be mentioned.

Means for mixing and dispersing the paint is not particularly limited and well-known mixing device, such as homogenizer, dissolver and planetary mixer, may be used. A total solid content ratio of metal oxide fine particles, a binder material and additive components is preferably 3 to 20 mass % and more preferably 5 to 15 mass % in the whole paint for bar coater coating.

As an application method of the paint, a variety of method, such as bar coater, air-knife coater, gravure coater, gravure reverse coater, reverse roll coater, lip coater, die coater, dip coater, offset printing, flexographic printing and screen printing, may be applied.

A melting and kneading temperature in an extrusion method may be a temperature, with which a mixture of the components above melts and is kneaded suitably. The extrusion method is not particularly limited and may be an inflation extrusion method or T die extrusion method, etc.

A thickness of the functional layer is not particularly limited but, for example, 0.5 μm or more, preferably 1 μm or more and, for example, 10 μm or less, preferably 3 μm or less and more preferably 2 μm or less or so. By forming the functional layer to have a film thickness in this range, adhesion to a processing table due to melting, etc. of the substrate film ca be prevented effectively.

Note that when the thickness of the functional layer is too thick (for example, exceeding 10 μm), cracks arise easily on the functional layer.

The functional layer is preferably adjusted to have a surface roughness on the opposite surface (exposed side) of the substrate film of 0.2 μm or more, preferably 0.3 μm or more and 1.5 μm or less and preferably 1.0 μm or less. By adjusting the surface roughness on the exposed side of the functional layer, adhesion to a processing table due to melting, etc. of the substrate film can be prevented more effectively.

The surface roughness here means arithmetic average roughness (Ra) defined by JIS B0601 on the exposed side of the functional layer. The arithmetic average roughness (Ra) may be measured by using, for example, a contact-type surface roughness tester (product name: SURFCOM 1500SD2-3DF manufactured by TOKYO SEIMITSU CO., LID.).

<Substrate Film>

The substrate film may be selected from well-known self-supporting type films. The substrate film preferably has a sheet shape having a uniform thickness or it may be in a mesh shape, etc. Also, the substrate film may be a single layer or has a multilayer structure of two or more layers.

As a material of the substrate film, for example, polymer films formed by an acrylic type resins, polyurethane type resins, polynorbornene type resins, polyalkylene glycol type resin, polyolefin type resins (polystyrene type resins and polyethylene type resins, etc.), polyimide type resins, polyester type resins, epoxy type resins, polyamide type resins, polycarbonate type resins, silicon type resins and fluorine type resins; metal sheets of copper, aluminum and stainless steel, etc.; nonwoven fabrics made of PP, PVC, PE, PU, PS, PO, PET and other polymer fibers, rayon, cellulose acetate and other synthetic fibers, cotton, silk, wool and other natural fibers, glass fiber, carbon fiber and other inorganic fibers; sheets added with a physical or optical function by performing drawing processing or impregnation processing, etc.; sheets including diene type (styrene-butadiene copolymer, butadiene, etc.), non-diene type (isobutylene-isoprene, polyethylene chloride, urethane type, etc.), thermoplastic type (thermoplastic elastomer, etc.) and other rubber components; or those obtained by combining one or more of those may be mentioned.

Among them, polyolefin type resins, specifically, polyethylene (for example, low density polyethylene, straight chain low density polyethylene, high density polyethylene, etc.), polypropylene (for example, drawn polypropylene, non-drawn polypropylene, etc.), ethylene copolymers, propylene copolymers, ethylene-propylene copolymer, etc. are preferable. When the substrate film has a multilayer structure, it is preferable that at least one layer is formed by a polyolefin type resin.

Particularly, as explained below, it is preferable to select from these substrate film materials those hard to be cut by a laser light for cutting workpieces in consideration of at least one characteristic, preferably all the characteristics of light transmissivity, stacked state, elongation at break, light absorption coefficient, melting point, thickness, strength at break, specific heat, etching rate, Tg, thermal deformation temperature, decomposition temperature, linear expansion coefficient, thermal conductivity and specific gravity, etc.

The substrate film preferably has a thickness of 50 μm or more, more preferably 100 μm or more, 150 μm or more and further preferably 50 to 500 μm or so. Thereby, operability and workability can be secured in respective steps of, for example, sticking to a semiconductor water, cutting of the semiconductor wafer, removing from the semiconductor chip, etc.

The substrate film preferably has transmissivity of a laser light, specially a laser light having a wavelength of around 355 nm to around 600 nm, of about 50% or more, preferably about 55% or more, more preferably about 60% or more and furthermore preferably about 65% or more. The light transmissivity may be measured, for example, by using an ultraviolet visible light spectrophotometer. Thereby, deterioration of the substrate film itself due to a laser light can be prevented. Note that light transmissivity of the substrate film means a value in a state without a functional layer.

The substrate film preferably has a multilayer structure of two or more layers of different materials. Here, a different material means not only having a different composition but includes those having the same composition but different characteristics because of a different molecular structure or molecular weight, etc. For example, it is suitable to stack those having at least one different characteristic feature among the above-mentioned light absorption coefficient, melting point, strength at break, elongation at break, light transmissivity, specific heat, etching rate, thermal conductivity, Tg, thermal deformation temperature, decomposition temperature, linear expansion coefficient, and specific gravity, etc.

Among them, at least one layer in the multilayer structure of two or more layers is preferably made by a resin not including any benzene ring, or a chain saturated hydrocarbon type resin, for example, a polyolefin type resin.

As polyolefin type resins, one or more kinds selected from polyethylene, polypropylene, ethylene copolymer, propylene copolymer, ethylene-propylene copolymer, polybutadiene, polyvinyl alcohol, polymethyl pentene, ethylene-vinyl acetate copolymer, polyvinyl acetate, etc. may be preferably used. Among them, it is preferably at least one kind selected from ethylene and propylene type (co)polymer, furthermore, polyethylene, polypropylene, ethylene copolymer, propylene copolymer, ethylene-propylene copolymer. By selecting from these materials, it is possible to hit a balance between suitable extensibility and suitable strength against laser processing.

When the substrate film has a multilayer structure, it is preferable to include both a polyethylene resin layer and a polypropylene resin layer. Particularly, a two-layer or three-layer structure including these layers is preferable. In that case, it is more preferable that a polypropylene resin layer is positioned far from an adhesive layer. For example, in the case of a two-layer structure, it is preferable that a polypropylene resin layer is placed on the back surface side of the substrate film and a polyethylene resin layer is placed on the adhesive layer side and, in the case of a three-layer structure, it is preferable that a polypropylene resin layer is placed on the back surface of the substrate film or on one layer closer position to the adhesive layer side and a polyethylene resin layer is placed on the adhesive layer side. It is because such arrangements enable to secure suitable extensibility of the substrate film because of the layer formed by the polypropylene resin, which is a relatively soft resin, on the most back surface side even if a part of the substrate film is damaged during laser processing.

The substrate film preferably includes at least two or more layers having different elongation at break. Elongation at break may be measured, for example, by using a versatile tensile tester at a tensile speed of 200 mm/min. based on JIS K-7127. Difference of elongation at break is not particularly limited but is, for example, about 100% or more and preferably about 300% or more. In that case, a layer with a larger elongation at break is preferably placed away from the adhesive layer. Namely, it is preferable that a layer having good extensibility is arranged on the side hard to be cut by a laser light.

Particularly, the substrate film has elongation at break of preferably 100% or more. When the substrate film has a multilayer structure, it is not necessary that all layers have elongation at break of 100% or more, but the layer having good extensibility is preferably arranged on the most back surface side of the substrate film. Particularly, a substrate film having elongation at break of 100% or more and strength at break in the range explained above is preferable because chips are easily separated from one another after performing laser dicing, stretching the dicing sheet and cutting a workpiece into the chips.

The substrate film preferably includes at least two or more layers having different strength at break. Here, the strength at break may be measured by using a versatile tensile tester with a tensile speed of 200 mm/min. based on JIS K-7127. Difference of strength at break is not particularly limited but is preferably, for example, about 20 MPa or more and preferably about 50 MPa or more. In that case, it is preferable that a layer having a higher strength at break is placed away from the adhesive layer. Namely, it is preferable that a layer having strength hard to be cut by a laser light is arranged on the back surface of the substrate film.

The substrate film preferably includes a layer having a melting point of 90° C. or higher. Thereby, melting of the substrate film due to laser light irradiation can be prevented effectively. The melting point is preferably 95° C. or higher, more preferably 100° C. or higher and furthermore preferably 110° C. or higher. When the substrate film has a single-layer structure, the composing layer itself has to have a melting point of 90° C. or higher, while in the case of a multilayer structure, not all of the layers have to have a melting point of 90° C. or higher but preferably at least one layer has a melting point of 90° C. or higher. In that case, it is preferable that the layer is arranged on the side to be a back surface (for example, a side to contact with a chuck table) at laser processing.

The substrate film preferably has larger specific heat. The specific heat is, for example, about 0.5 J/g·K or more, preferably 0.7 J/g·K or more, more preferably 0.8 J/g·K or more, furthermore preferably 1.0 J/g·K or more and still further preferably 1.1 J/g·K or more and most preferably 1.2 J/g·K or more. When the specific heat is relatively large, the substrate film itself becomes hard to be heated by heat generated by a laser light and a part of the heat is easily released to outside the substrate film. As a result, the substrate film is hard to be processed, cutting of the substrate film is suppressed to minimum and partial adhesion of back surface to a processing table can be prevented. The specific heat may be measured based on JIS K7123. Specifically, it is obtained by actually measuring a quantity of heat necessary for raising a temperature of a test piece by 10° C./mm² by using a differential scanning calorimeter (DSC).

The substrate film preferably has a low etching rate. For example, the etching rate is preferably 0.3 to 1.5 μm/pulse with laser light intensity of 1 to 5 J/cm² or so, more preferably 0.3 to 1.2μ/pulse, more preferably 0.3 to 1.1 μ/pulse. Particularly, it is preferably 0.9μ/pulse or less, more preferably 0.7μ/pulse or less with laser light intensity of 1 to 2 J/cm² or so. When the etching rate is low, cutting of the substrate film itself can be prevented.

The substrate film preferably has a characteristic that a glass transition point (Tg) is about 50° C. or lower, preferably about 30° C. or lower and more preferably about 20° C. or 0° C. or lower, or a thermal deformation temperature is about 200° C. or lower, preferably about 190° C. or lower, more preferably about 180° C. or lower and furthermore preferably about 170° C. or lower, alternatively, a specific gravity is about 1.4 g/cm³ or lower, preferably about 1.3 g/cm³ or lower, more preferably about 1.2 g/cm³ or lower and furthermore preferably about 1.0 g/cm³ or lower. When those characteristics are provided, cutting of the substrate film can be suppressed to minimum and it becomes advantageous for preventing partial adhesion of the back surface to a processing table.

The Tg and thermal deformation temperature may be measured, for example, by using a measurement method of a general plastic transition temperature based on JIS K7121 (specifically, a differential thermal analysis (DTA) and differential scanning calorimetry analysis (DSC), etc.). The specific gravity may be measured, for example, by using a generally-known plastic density (specific gravity) measurement method (specifically, water displacement method, pycnometry method, sink float method and density gradient method, etc.) in JIS K7112.

A surface of the substrate film may be subjected to a well-known surface treatment, for example, a chemical or physical treatment, such as a chronic acid treatment, exposure to ozone, exposure to flames, exposure to high-pressure electric shock and ionizing radiation treatment, or a coating treatment with an undercoat agent (for example, a later-explained adhesive substance), etc. in order to improve adhesiveness and retention, etc. with adjacent materials, such as a table, etc. in a processing apparatus.

<Adhesive Layer>

The adhesive layer to be stacked on the front surface of the substrate film is not particularly limited and may be formed by using a well-known adhesive agent composition in the field, containing an energy line curing type resin to be cured, for example, by an ultraviolet ray, electron ray and other radiation, a thermosetting resin and thermoplastic resin, etc. Particularly, in order to improve releasability of a workpiece, use of an energy line curing type resin is preferable.

By irradiating an energy line, adhesive force can be reduced due to formation of three-dimensional mesh structure in an adhesive agent, which results in easy release after use. The adhesive agent is not particularly limited and, for example, those described in Japanese Patent Unexamined Publication (Kokai) No. 2002-203816, No. 2003-142433, No. 2005-19607, No. 2005-279698, No. 2006-35277 and No. 2006-111659, etc. may be used.

Specifically, rubbers, such as natural rubber and various synthetic rubber, or an acrylic type polymer, such as poly(meth)acrylic acid alkyl produced from acrylonitrile and acrylic acid alkyl or polymethacrylic acid alkyl having straight-chain or branched alkyl group of 1 to 20 carbon atoms may be mentioned.

The adhesive agent may be added with a polyfunctional monomer as a crosslinking agent. As a crosslinking agent, hexanediol di(meth)acrylate, (poly)ethylene glycol di(meth)acrylate and urethane acrylate, etc. may be mentioned. Those may be used alone or in combination of two or more kinds.

To obtain an energy line curing type adhesive, it is preferable to combine with a so-called photopolymerizing composition, such as a monomer or oligomer easily reactive to light irradiation. To raise examples, urethane, methacrylate, trimethylpropane trimethacrylate, tetramethylol methane tetramethacrylate and 4-butylene glycol dimethacrylate, etc. may be mentioned.

In that case, it may also contain a photopolymerization initiator. As an initiator, 4-(4-hydroxyethoxy)phenyl(2-hydroxy-2-propyl)ketone and other acetophenone compounds, benzoin ethylether and other benzoin ether compounds, ketal compounds, aromatic sulfonyl chloride compounds, optically active oxime compounds and benzophenone compounds may be mentioned. Those may be used alone or in combination of two or more kinds.

To obtain a photosensitive adhesive agent, a so-called heat foaming component (decomposing type or microcapsule type) may be used, as well. For example, what described in European Patent No. 0523505, etc. may be used.

The adhesive agent may be mixed with any additives, such as a tackifier, filler, pigment, antioxidant, stabilizer and softener, when needed.

A thickness of the adhesive layer is not particularly limited but may be, for example, about 300 μm or less and 3 to 200 μm or so in consideration of not letting undesirable adhesive agent residual remain after removing the laser dicing auxiliary sheet of the present invention from a semiconductor wafer, etc.

The adhesive layer to be stacked on the front surface of the substrate film may be formed by a well-known method in this field. For example, as explained above, it is formed by preparing an adhesive agent component, applying the same to the substrate film and drying. As an application method of the adhesive agent component, a variety of methods may be applied, such as bar coater, air-knife coater, a gravure coater, gravure reverse coater, reverse roll coater, lip coater, die coater, dip coater, offset printing, flexographic printing and screen printing. Also, a method of separately forming an adhesive layer on a releasable liner and then sticking the same to the substrate film, etc. may be applied, as well.

<Use Method of Auxiliary Sheet for Laser Dicing>

The auxiliary sheet for laser dicing of the present invention may be used preferably for a variety of processing using a laser light, for example, a manufacturing procedure of a semiconductor chip as follows. Particularly, the auxiliary sheet for laser dicing of the present invention can be used for the purpose requiring a high irradiation output of laser light, for example, processing an optical device wafer using a substrate having high hardness, such as a sapphire substrate, a substrate obtained by depositing silver on copper, etc.

Below, an explanation will be made by showing an example of a manufacturing procedure of a semiconductor chip.

It may be used for the procedure of producing semiconductor chips, etc. by sticking the auxiliary sheet for laser dicing of the present invention to the opposite surface of a circuit-formed surface of a semiconductor wafer, irradiating a laser light from the circuit-formed surface of the semiconductor wafer, and dividing the semiconductor wafer into individual pieces, one circuit on each piece.

Formation of circuits on the wafer surface is performed by a well-known method, such as an etching method and lift-off method. The circuits are formed in a grid on an inner circumferential portion of the surface of the wafer leaving an extra space with no circuit on a region of several millimeters from the outer circumferential edge. A thickness of the wafer before grinding is not particularly limited and is normally 500 to 1000 μm or so.

When performing grinding processing on a back surface of the semiconductor wafer, a surface protective sheet may be adhered to the circuit surface side to protect circuits on the surface. The back surface grinding processing is performed by fixing the circuit side of the wafer to a chuck table, etc. and grinding with a grinder the back surface with no circuits formed. When grinding the back surface, the entire back surface is ground to a predetermined thickness first, then, only an inner circumferential portion on the backside, which corresponds to a circuit formation portion (inner circumferential portion) on the front surface, is ground, and a back surface region corresponding to the extra portion, on which circuits are not formed, is left without being ground. As a result, on the semiconductor wafer after grinding, only the inner circumferential portion on the back surface is ground to be furthermore thinner and a ring-shaped raised portion is left on the outer circumferential portion. The back surface grinding method as above may be performed by a well-known method. After the back surface grinding process, processing of removing a fractured layer generated by the grinding may be performed.

Subsequently to the back surface grinding process, etching processing or other processing involving heating, and a treatment with a high temperature, such as deposition of a metal film or baking of an organic film, may be performed on the back surface in accordance with need. When performing a high temperature treatment on the back surface, it is performed after removing the surface protective sheet.

After the back surface grinding process, the adhesive layer of the auxiliary sheet for laser dicing of the present invention is placed facing to the opposite surface of the circuit-formed surface of the wafer and applied. Application of the auxiliary sheet for laser dicing to the wafer is generally done by a device called mounter, but it is not limited to that.

Next, after the wafer applied with the auxiliary sheet for laser dicing is placed on a processing table of a dicing apparatus with the functional layer side facing downward, a laser light is irradiated from the wafer side so as to dice the wafer.

In the present invention, a short wavelength laser light having a high energy density is preferably used to fully cut a semiconductor wafer having high hardness. As a short wavelength laser as such, for example, a laser having an oscillation wavelength of 400 nm or less, specifically, a KrF eximer laser having an oscillation wavelength of 248 nm, XeCI eximer laser with 308 nm, the third harmonic (355 nm) and fourth harmonic (266 nm) of an Nd-YAG laser, etc. may be mentioned. Also, a laser having an oscillation wavelength of 400 nm or more (for example, a titanium sapphire laser, etc. having a wavelength around 750 to 800 nm with a pulse width of 1×10⁻⁹ second (0.000000001 second) or less) may be used, as well.

Intensity and illuminance of the laser light depend on a thickness of the wafer to be cut and may be at a level capable of cutting the wafer fully.

The laser light is irradiated to streets between circuits to divide the wafer into chips, one circuit on each chip. The number of times that the laser light scans on one street may be one time or more. Preferably, irradiation of the laser light is performed while monitoring an irradiation position of the laser light and positions of the streets between circuits and aligning the laser light. A scan speed (feeding speed in processing) of the laser light is 80 mm/sec. or higher, preferably 100 mm/sec. or higher and more preferably 130 mm/sec. or higher considering the productivity.

After the dicing finishes, semiconductor chips are picked up from the laser dicing auxiliary sheet. The pickup method is not particularly limited and a variety of well-known method may be applied. For example, the method of poking each semiconductor chip from below with a needle from the laser dicing auxiliary sheet side and picking up the poked semiconductor chip by using a pickup device, etc. may be mentioned. When the adhesive layer of the laser dicing auxiliary sheet is formed by an energy line curing adhesive agent, an energy line (ultraviolet, etc.) is irradiated to the adhesive layer to reduce the adhesiveness before picking up the chips.

Picked up semiconductor chips are subjected to die bonding and resin sealing by a normal method, so that semiconductor devices are manufactured.

By using the laser dicing auxiliary sheet of the present invention, holding an opposite surface from the circuit-formed surface of the semiconductor wafer, and irradiating a laser light from the circuit-surface side of the semiconductor wafer to dice, the semiconductor wafer can be cut fully without cutting the laser dicing auxiliary sheet fully, so that semiconductor chips can be produced with preferable workability. Also, since a functional layer is stacked on the back surface of the substrate film, even if an irradiation output (W) of a laser light to be used for dicing a semiconductor wafer having high hardness is high as, for example, 7 W or higher and a scan speed is fast as, for example, 80 mm/sec. or higher, the substrate film does not melt at a laser light irradiated part, consequently, it is possible to prevent the phenomenon that the back surface of the substrate film partially adheres to a processing table in a dicing apparatus.

An explanation was made above on the example of using a semiconductor wafer as a workpiece, however, the auxiliary sheet for dicing of the present invention is not limited to that and may be also used for dicing a semiconductor package, optical device wafer using a sapphire substrate or a substrate obtained by depositing silver on copper, etc., glass substrate, ceramic substrate, FPC and other organic material substrate, metal materials of a precision component, etc. As already explained above, the dicing auxiliary sheet of the present invention is particularly suitable for dicing a workpiece using a substrate having high hardness, which requires a high irradiation output of a laser light.

### EXAMPLES

Below, examples of more specified embodiment of the present invention (an example of forming a functional layer by an application method) will be explained further in detail. In the examples, “part” and “%” are based on weight unless otherwise mentioned.

Note that fine particles A and B and resins C to E were as follows.

[Fine Particle A] colloidal silica (SNOWTEX ST-C: NISSAN CHEMICAL INDUSTRIES, LTD., silica fine particle dispersion liquid (silica sol), solid content: 20%, average particle diameter of primary particles: 10 to 15 nm)
[Fine Particle B] zirconia (NanoUse ZR-30BFN: NISSAN CHEMICAL INDUSTRIES, LTD., zirconia fine particle dispersion liquid (zirconia sol), solid content: 30%, average particle diameter of primary particles: 10 to 30 nm)
[Resin C] modified polyolefin resin (ARROWBASE TC4010: UNITIKA LTD., acid-modified polyolefin resin (PP skeleton) aqueous dispersion, active ingredient concentration: 25%, acid-modified amount: 5 mass % or less, melting point: 130 to 150° C., not containing any emulsifier)
[Resin D] polyamide resin (ME-X025: UNITIKA LTD., polyamide resin aqueous dispersion, active ingredient concentration: 25%, melting point: 150 to 160° C.)
[Resin E] polyester resin (VYLON GK880: TOYOBO CO., LTD., solvent soluble, active ingredient concentration: 100%, melting point: 84° C., weight-average molecular weight: 18000)

### Experimental Examples 1 to 10

### 1. Producing Laser Dicing Auxiliary Sheet

On one surface of a 160 μm polyethylene film as a substrate, an application liquid for an adhesive layer having the composition below was applied by a bar coating method so that a thickness after drying becomes 25 μm and dried to form an adhesive layer. Next, on the other surface of the polyethylene film, an application liquid for a functional layer having the composition below was applied by a bar coating method so that a thickness after drying becomes 1.5 μm and dried to form a functional layer, consequently, a laser dicing auxiliary sheet was produced.

### <Composition of Adhesive Layer Application Liquid>

| | |
|---|---|
| acrylic type pressure-sensitive adhesive agent | 100 parts |
| (COPONYL N4823: The Nippon Synthetic Chemical | |
| Industry Co., Ltd.) | |
| isocyanate compound | 0.44 part |
| (Coronate L45E: Nippon Polyurethane Industry Co., Ltd.) | |
| diluting solvent | 54 parts |

### <Composition of Function Layer Application Liquid>

metal oxide fine particles kinds and blending amount as shown in Table 1

thermoplastic resin kinds and blending amount as shown in Table 1

solvent kinds and blending amount as shown in Table 1

TABLE 1

| | Application Liquid for Functional Layer (part by weight) | | | | | | | | | | |
|---|---|---|---|---|---|---|---|---|---|---|---|
| | Metal Oxide Fine | | | | | | | | | | |
| | Particles (part) | | | | | | | | | | |
| | | | Primary | | | | | | | | |
| | | | Particle | Thermoplastic | | | | | | | |
| Experimental | | | Diameter | Resin (part) | | | | Solvent (part) | | | |
| examples | A | B | (nm) | C | D | E | State | IPA | Water | MEK | Toluene |
| 1 | 29.3 | — | 10-15 | 16 | — | — | Emulsion | 25 | 30 | — | — |
| 2 | 24.4 | — | 10-15 | 20 | — | — | | 25 | 30 | — | — |
| 3 | 19.5 | — | 10-15 | 24 | — | — | | 25 | 30 | — | — |
| 4 | — | 16.7 | 10-30 | 20 | — | — | | 25 | 38 | — | — |
| 5 | 29.3 | — | 10-15 | — | 16 | — | | 25 | 30 | — | — |
| 6 | 24.4 | — | 10-15 | — | 20 | — | | 25 | 30 | — | — |
| 7 | 19.5 | — | 10-15 | — | 24 | — | | 25 | 30 | — | — |
| 8 | — | 16.7 | 10-30 | — | 20 | — | | 25 | 38 | — | — |
| 9 | 24.4 | — | 10-15 | — | — | 5 | Solution | — | — | 35 | 35 |
| 10 | — | 16.7 | 10-30 | — | — | 5 | | — | — | 39 | 39 |

### <2. Evaluation of Laser Dicing Auxiliary Sheet>

### 2-1. Surface Roughness Value of Functional Layer

On each of the produced laser dicing auxiliary sheet (hereinafter, simply referred to as “an auxiliary sheet”), a value of arithmetic average roughness (Ra) based on JIS B0601 was measured by using a contact-type surface roughness tester (product name: SURFCOM 1500SD2-3DF, TOKYO SEIMITSU CO., LID.) at random three positions (position n1, position n2 and position n3) on the functional layer. An average (Ave.) of the measured 3 points was finally used as the Ra value of the functional layer exposure side. The results are shown in Table 2.

### 2-2. Cut Suitability

By using a 2 kg rubber roller regulated in JIS K6253, an adhesive layer surface of each of the produced auxiliary sheets was pressed against and bonded with a prepared silicon wafer (8 inches) under the condition of rolling back and forth once on the wafer (step 1). Next, on a chuck table of a dicing apparatus having a sucking board made of quartz glass, a silicon wafer stuck to the auxiliary sheet was placed with the functional layer surface facing downward (step 2). Next, based on the laser irradiation condition below, a laser light was irradiated by using a Nd-YAG laser from the wafer side to perform cutting processing on the wafer (full cut) (step 3), and cut suitability was evaluated based on the following criteria. The results are shown in Table 2.

∘: The substrate of the auxiliary sheet was not cut fully (excellent).
x: The substrate of the auxiliary sheet was cut fully (defective).

### <Laser Irradiation Condition>

wavelength: 355 nm
repetition frequency: 100 kHz
average output: 7 w
irradiation times: 6 times/1 line
pulse width: 50 ns
light conversion spot: oval shape (100 μm in longitudinal axis and 10 μm in short axis)
processing feed speed: 100 mm/sec.

### 2-3. Prevention of Adhesion to Chuck Table

After the operations in steps 1 to 3 in 2-2 above, the auxiliary sheet together with respective semiconductor chips were pulled up from the chuck table by a conveyor arm and prevention of adhesion was evaluated based on the following criteria. The results are shown in Table 2.

[symbol]

: The auxiliary sheet did not adhere to the chuck table at all and the auxiliary sheet was pulled up from the chuck table without any resistance (very excellent).
∘: About 3% of the whole area of the auxiliary sheet adhered to the chuck table but the auxiliary sheet was able to be pulled up from the chuck table (excellent).
Δ: About 5% of the whole area of the auxiliary sheet adhered to the chuck table but the auxiliary sheet was able to be pulled up from the chuck table (good).
x: All (100%) of the entire area of the auxiliary sheet adhered to the chuck table, consequently, the auxiliary sheet could not be pulled up from the chuck table (defective).

TABLE 2

Evaluation

| | Ra of | | Adhesion |
|---|---|---|---|
| Experimental | Functional | Cut | Prevention |
| examples | Layer (μm) | Suitability | Property |
| 1 | 0.7 | ◯ | ◯ |
| 2 | 0.5 | ◯ | ⊚ |
| 3 | 0.7 | ◯ | ◯ |
| 4 | 0.4 | ◯ | Δ |
| 5 | 0.4 | ◯ | Δ |
| 6 | 0.7 | ◯ | ◯ |
| 7 | 0.4 | ◯ | Δ |
| 8 | 0.4 | ◯ | Δ |
| 9 | 0.1 | ◯ | X |
| 10 | 0.1 | ◯ | X |

### <3. Consideration>

As shown in Table 1 and Table 2, when the thermoplastic resin in the functional layer application liquid was an emulsified state (Experimental examples 1 to 8), all functional layers formed by using the application liquid were confirmed to be effective. Particularly when a blending ratio (in terms of solid content) of the metal oxide fine particles and a thermoplastic resin in the application liquid was 55 mass % of metal oxide fine particles and 45 mass % of emulsion particles of a thermoplastic resin, and an acid-modified polyolefin resin was used as the thermoplastic resin (Experimental example 2), it was confirmed to be most effective.

On the other hand, when solvent soluble type was used as the thermoplastic resin (Experimental examples 9 and 10), even if the blending ratio (in terms of solid content) of the metal oxide fine particles and a thermoplastic resin in the application liquid was preferable as 10 to 90 mass % of metal oxide fine particles and 90 to 10 mass % of emulsion particles of a thermoplastic resin, it was confirmed that the adhesion prevention property was poor.

Although it is not shown in Table 1 or Table 2, when a silica filler (PLV-4, Tatsumori Ltd.) having an average particle diameter of 4 μm was used as the fine particle, even if emulsion particles of a thermoplastic resin was blended with a preferable ratio, it was confirmed that their evaluation was equivalent to or poorer than those of the Experimental examples 1 to 8.

What is claimed is:

1. An auxiliary sheet for laser dicing, wherein an adhesive layer is stacked on one surface of a substrate film, a functional layer is stacked on the other surface of the substrate film, and the functional layer is formed by using a mixture containing metal oxide fine particles, in which an average particle diameter of primary particle is 5 to 400 nm, and emulsion particles of a thermoplastic resin as a binder material.

2. The auxiliary sheet for laser dicing according to claim 1, wherein a thickness of the functional layer is adjusted to 0.5 μm or more and 10 μm or less.

3. The auxiliary sheet for laser dicing according to claim 2, wherein surface roughness (Ra) on an exposed side of the functional layer is adjusted to 0.2 μm or more and 1.5 μm or less.

4. The auxiliary sheet for laser dicing according to claim 3, wherein a ratio of the metal oxide particles to emulsion particles of a thermoplastic resin is adjusted to 10-90 mass %:90-10 mass % in terms of solid content when a total solid content in the mixture is 100 mass %.

5. The auxiliary sheet for laser dicing according to claim 1, wherein surface roughness (Ra) on an exposed side of the functional layer is adjusted to 0.2 μm or more and 1.5 μm or less.

6. The auxiliary sheet for laser dicing according to claim 1, wherein a ratio of the metal oxide particles to emulsion particles of a thermoplastic resin is adjusted to 10-90 mass %:90-10 mass % in terms of solid content when a total solid content in the mixture is 100 mass %.

7. The auxiliary sheet for laser dicing according to claim 2, wherein a ratio of the metal oxide particles to emulsion particles of a thermoplastic resin is adjusted to 10-90 mass %:90-10 mass % in terms of solid content when a total solid content in the mixture is 100 mass %.
